(19) United States
(12) Patent Application Publication
(10) Pub. No.: US 2011/0029256 A1
(43) Pub. Date: Feb. 3, 2011

(54) GRAPHICALLY REPRESENTING A NUMBER OF MEASUREMENT DATA SETS

(75) Inventor: Michael Frank, Waldbronn (DE)

Correspondence Address: Agilent Technologies, Inc. in care of:;CPA Global, P. O. Box 52050, Minneapolis, MN, 55402, US

(73) Assignee: AGILENT TECHNOLOGIES, INC., Loveland, CO (US)

(21) Appl. No.: 12/845,851

(22) Filed: Jul. 29, 2010

(30) Foreign Application Priority Data
Aug. 3, 2009 (EP) 09176051.3

(51) Int. Cl. G01N 30/16; G01N 30/02; G01N 21/33; H01J 49/26; G01J 3/44; G01R 33/48; G21K 4/00; G01N 15/02

(52) U.S. Cl. 702/25; 73/61.52; 356/51; 250/282; 356/301; 324/307; 378/41; 356/335

(57) ABSTRACT

Disclosed is graphically representing each of a number of measurement data sets as a variation of at least one parameter, wherein each measurement data set results from a measurement, by: [A] selecting a plurality of the measurement data sets to be graphically represented, [B] graphically representing one of the selected measurement data sets as a primary measurement data set in a first graphical style, and [C] graphically representing each one of the at least one remaining selected measurement data sets as secondary measurement data set in a graphical style deviating in at least one feature from the first graphical style. Upon a first change request, a different one of the selected measurement data sets is graphically represented as the primary measurement data set in the first graphical style, and continuing with [C].

### BACKGROUND ART

The present invention relates to graphically representing measurement data sets as a variation of at least one parameter, wherein each measurement data set results from a measurement, in particular in a high performance liquid chromatography application.

In high performance liquid chromatography (HPLC, see e.g. http://en.wikipedia.org/wiki/HPLC), a liquid has to be provided usually at a very controlled flow rate (e.g. in the range of microliters to milliliters per minute) and at high pressure (typically 20-100 MPa, 200-1000 bar, and beyond up to currently 200 MPa, 2000 bar) at which compressibility of the liquid becomes noticeable. For liquid separation in an HPLC system, a mobile phase comprising a sample fluid with compounds to be separated is driven through a stationary phase (such as a chromatographic column), thus separating different compounds of the sample fluid which may then be identified.

The mobile phase, for example, a solvent, is pumped under high pressure typically through a column of packing medium, and the sample (e.g. a chemical or biological mixture) to be analyzed is injected into the column. As the sample passes through the column with the liquid, the different compounds, each one having a different affinity for the packing medium, move through the column at different speeds. Those compounds having greater affinity for the packing medium move more slowly through the column than those having less affinity, and this speed differential results in the compounds being separated from one another as they pass through the column.

The mobile phase with the separated compounds exits the column and passes through a detector, which identifies the molecules, for example by spectrophotometric absorbance measurements. A two-dimensional plot of the detector measurements against elution time or volume, known as a chromatogram, may be made, and from the chromatogram the compounds may be identified. For each compound, the chromatogram displays a separate curve or “peak”.

Examples for typical representations of chromatography data are shown in the brochure “Agilent 1200 Series Fluorescence Detector”, published Feb. 1, 2006, Publication Number 5989-4338 EN. The upper window on page 2 shows plural chromatograms (derived for different wavelengths) each graphically represented in a different color. The lower picture on page 2 shows a three dimensional chromatogram plot, as the variation of intensity over time and wavelength.

### DISCLOSURE

It is an object of the invention to provide an improved graphical representation of measurement data sets in particular for HPLC applications. The object is solved by the independent claim(s). Further embodiments are shown by the dependent claim(s).

According to the present invention, a method of graphically representing each of a number of measurement data sets is provided. Each measurement data set represents a variation of at least one parameter and results from a measurement. The method comprises selecting a plurality of the measurement data sets to be graphically represented. One of the selected measurement data sets is graphically represented as a primary measurement data set in a first graphical style. Each one of the remaining selected measurement data sets is graphically represented as secondary measurement data set in a graphical style deviating in at least one feature from the first graphical style. Upon a first change request, a different one of the selected measurement data sets is graphically represented as the primary measurement data set (in the first graphical style), and the remaining selected measurement data sets are graphically represented as secondary measurement data set.

The invention thus provides a selection of measurement data sets and distinguishes the selected measurement data sets by graphically representing one as the primary measurement data set, in the first graphical style, and the other(s) as secondary measurement data set in a different graphical style. The first change request allows separating a different one of the selected measurement data sets as the primary measurement data set. In this way, for example a large number of measurement data sets can be reduced to only the selected measurement data sets, and the reduced number of measurement data sets can be distinguished and compared with the other one(s) of the selected measurement data sets. Thus, the reduced number of measurement data sets can be individually analyzed and compared, for example one after the other. This in particular useful for analyzing a large number of measurement data sets, for example, when analyzing a large number of chromatograms or spectra or electrophoretograms.

In one embodiment, the plurality of measurement data sets are selected from a group of measurements data sets being larger than the selected plurality of the measurement data sets, so that the selected plurality of measurement data sets represents a subset of the group of measurement data sets. This embodiment turns out to be in particular useful when handling a large number of measurement data sets, so that a two-step data reduction and analysis is provided by first selecting only certain of the group of measurement data sets and then individually distinguishing the selected primary measurement data set from the remaining secondary measurement data set(s).

In one embodiment, the selected measurement data sets are reduced to the primary measurement data set and one or more measurement data sets “neighboring” to the primary measurement data set. Such “neighboring” can be, for example in case the measurement data sets are derived successively over time (such as often chromatograms are by taking plural chromatograms one after the other over time), in that the neighboring measurement data sets are selected as the measurement data sets derived in time just before or just after deriving the primary measurement data sets. Neighboring in this case means successive in order of deriving the measurement data sets. However, it is clear that such neighboring is not limited to directly successive measurement data sets but may also cover such measurement data sets within a certain time frame.

In another example, the measurement data sets are derived each for a different value of a second parameter, such as a plurality of chromatograms as variations over time and wavelengths. The second parameter is different from the at least one parameter to be graphically represented for the measurement data sets. The neighboring measurement data sets are selected as such measurement data sets with values of the second parameter next, previous or at least being close to the value of the secondary parameter of the primary measurement data set. In this context “neighboring” means similar data measurement data sets with respect to the second parameter.

In one embodiment, the measurement data sets are graphically represented in one window, for example, in a computer screen window as well known in the art.

In one embodiment, a different plurality of the measurement data sets is selected upon a second change request and graphically represented in accordance with the aforesaid. This allows analyzing, for example, a large number of measurement data sets by first deriving a subset of measurement data sets and analyzing those by distinguishing a respective primary measurement data set from the other selected measurement data sets. Then a different subset can be selected and analyzed accordingly, so that the initial group of measurement data sets can be reduced and analyzed stepwise.

In one embodiment, the deviating feature can be one of transparency, color shading, gray shading, intensity, sharpness of the drawn line, or a combination thereof. This allows distinguishing the primary measurement data set from the secondary measurement data set. In a preferred embodiment, the first graphical style of the primary measurement data set has the lowest transparency, and the secondary measurement data sets all have a higher transparency, which might be the same or different for each of the primary measurement data sets. Preferably, the first graphical style is no transparency (e.g. solid). The same may also apply for the gray shading and intensity, so that the first graphical style has the darkest gray shading or the highest intensity, while the secondary measurement data sets use lighter gray shading or lower intensities. The same may also apply for sharpness, so that the first graphical style has the highest sharpness, while the secondary measurement data sets use higher blur.

In one embodiment, the first graphical style is a solid line, and the deviating feature is in that the line for the primary measurement data sets is non-solid, such as dotted, dashed or a combination thereof.

The measurement data sets may represent a variation of one parameter over another parameter, such as a measured value of intensity over a measured value of time, e.g., as provided in liquid separation such as chromatography. Accordingly, it might also be a variation of one parameter over a variation of a different parameter as in the aforementioned example. Other examples might be an electrophoretogram resulting from an electrophoretic separation, or various spectra resulting e.g. from UV/VIS spectroscopy, mass spectrometry, nuclear magnetic resonance (NMR) spectroscopy, infrared (IR) or Raman spectroscopy, x-ray spectroscopy, etc. Also, a particle size spectrum resulting from particle size analysis might be used as measurement data set.

In one embodiment, graphically representing a respective measurement data set comprises representing the measurement data set in a multi-dimensional visualization, which might be two-dimensional or three-dimensional. One dimension represents one parameter and another dimension represents a parameter causing the variation of the one parameter. As an example, the parameter might be intensity of absorbance or fluorescence in a HPLC detector, with the intensity varying over time, for example, as result of a mobile phase (containing the sample to be separated) driven through the system.

In one embodiment, graphically representing a respective measurement data set comprises representing the measurement data set as a two-dimensional projection of a three-dimensional data set. Each measurement data set represents a variation of the third dimension of the three-dimensional data set. Such three-dimensional data set can be a three-dimensional chromatogram showing variations over time and for example wavelength.

In one embodiment, a scaling is used for the graphical representation, for example an automatic scaling, so that all measurement data sets are scaled in the same way (e.g. having a common abscissa and/or ordinate).

In one embodiment, the change request, which might be the first and/or the second change request, is a user request (i.e. initiated by a user of the method) allowing the user to actively change the selection of the primary measurement data set and/or the subset of the selected measurement data sets. Such user request might be initiated or comprise a mouse scrolling (for example using wheel or other rotational movement tool of a computer mouse, or one of left or right click of the computer mouse), pressing of an arrow key, page up or down key, etc. of a computer terminal, or any other activation of a computer-human-interaction device such as a terminal, mouse, tablet, movement with a data glove, pointing stick, gesture recognition devices, etc.

Alternatively or in combination, the change request might be a time signal, for example a time signal after lapsing at a given time interval. This can allow an automatic variation of the selection of the primary measurement data set and/or the selected measurement data sets, so that, for example, all or only a subset of the measurement data sets is automatically displayed one after the other.

The invention might also be incorporated in an apparatus comprising a selector configured for selecting a plurality of the measurement data sets to be graphically represented. A graphical device is configured for graphically representing one of the selected measurement data sets as the primary measurement data set in the first graphical style, and for graphically representing each one of the remaining selected measurement data set as secondary measurement data set in a graphical style deviating in at least one feature from the first graphical style. A control unit is configured for receiving the first change request, and for instructing—upon receipt of the first change request—the graphical device for graphically representing a different one of the selected measurement data sets as the primary measurement data set, and for graphically representing each one of the remaining selected measurement data set as secondary measurement data sets.

Such apparatus might be part of a data processing unit in a fluid separation system for separating compounds of a sample fluid in a mobile phase.

Embodiments of the present invention might be embodied based on most conventionally available HPLC systems, such as the Agilent 1200 Series Rapid Resolution LC system or the Agilent 1100 or 1200 or 1200 Infinity HPLC series (both provided by the applicant Agilent Technologies—see www.agilent.com—which shall be incorporated herein by reference).

One embodiment comprises a pumping apparatus having a piston for reciprocation in a pump working chamber to compress liquid in the pump working chamber to a high pressure at which compressibility of the liquid becomes noticeable.

One embodiment comprises two pumping apparatuses coupled either in a serial or parallel manner. In the serial manner, as disclosed in EP 309596 A1, an outlet of the first pumping apparatus is coupled to an inlet of the second pumping apparatus, and an outlet of the second pumping apparatus provides an outlet of the pump. In the parallel manner, an inlet of the first pumping apparatus is coupled to an inlet of the second pumping apparatus, and an outlet of the first pumping apparatus is coupled to an outlet of the second pumping apparatus, thus providing an outlet of the pump. In either case, a liquid outlet of the first pumping apparatus is phase shifted, preferably essentially 180 degrees, with respect to a liquid outlet of the second pumping apparatus, so that only one pumping apparatus is supplying into the system while the other is intaking liquid (e.g. from the supply), thus allowing to provide a continuous flow at the output. However, it is clear that also both pumping apparatuses might be operated in parallel (i.e. concurrently), at least during certain transitional phases e.g. to provide a smooth(er) transition of the pumping cycles between the pumping apparatuses. The phase shifting might be varied in order to compensate pulsation in the flow of liquid as resulting from the compressibility of the liquid. It is also known to use three piston pumps having about 120 degrees phase shift.

The separating device preferably comprises a chromatographic column (see e.g. http://en.wikipedia.org/wiki/Column chromatography) providing the stationary phase. The column might be a glass or steel tube (e.g. with a diameter from 50 μm to 5 mm and a length of 1 cm to 1 m) or a microfluidic column (as disclosed e.g. in EP 1577012 or the Agilent 1200 Series HPLC-Chip/MS System provided by the applicant Agilent Technologies, see e.g. http://www.chem.agilent.com/Scripts/PDS.asp?IPage=38308). For example, a slurry can be prepared with a powder of the stationary phase and then poured and pressed into the column. The individual components are retained by the stationary phase differently and separate from each other while they are propagating at different speeds through the column with the eluent. At the end of the column they elute one at a time. During the entire chromatography process the eluent might be also collected in a series of fractions. The stationary phase or adsorbent in column chromatography usually is a solid material. The most common stationary phase for column chromatography is silica gel, followed by alumina. Cellulose powder has often been used in the past. Also possible are ion exchange chromatography, reversed-phase chromatography (RP), affinity chromatography or expanded bed adsorption (EBA). The stationary phases are usually finely ground powders or gels and/or are microporous for an increased surface; though in EBA a fluidized bed is used.

The mobile phase (or eluent) can be either a pure solvent or a mixture of different solvents. It can be chosen e.g. to minimize the retention of the compounds of interest and/or the amount of mobile phase to run the chromatography. The mobile phase can also been chosen so that the different compounds can be separated effectively. The mobile phase might comprise an organic solvent like e.g. methanol or acetonitrile, often diluted with water. For gradient operation water and organic is delivered in separate bottles, from which the gradient pump delivers a programmed blend to the system. Other commonly used solvents may be isopropanol, THF, hexane, ethanol and/or any combination thereof or any combination of these with aforementioned solvents.

The sample fluid might comprise any type of process liquid, natural sample like juice, body fluids like plasma or it may be the result of a reaction like from a fermentation broth.

The pressure in the mobile phase might range from 2-200 MPa (20 to 2000 bar), in particular 10-150 MPa (100 to 1500 bar), and more particular 50-120 MPa (500 to 1200 bar).

The HPLC system might further comprise a sampling unit for introducing the sample fluid into the mobile phase stream, a detector for detecting separated compounds of the sample fluid, a fractionating unit for outputting separated compounds of the sample fluid, or any combination thereof. Further details of HPLC system are disclosed with respect to the Agilent 1200 Series Rapid Resolution LC system or the Agilent 1100 HPLC series, both provided by the applicant Agilent Technologies, under www.agilent.com which shall be in cooperated herein by reference.

Embodiments of the invention can be partly or entirely embodied or supported by one or more suitable software programs, which can be stored on or otherwise provided by any kind of data carrier, and which might be executed in or by any suitable data processing unit. Software programs or routines can be preferably applied in or by the control unit.

### BRIEF DESCRIPTION OF DRAWINGS

Other objects and many of the attendant advantages of embodiments of the present invention will be readily appreciated and become better understood by reference to the following more detailed description of embodiments in connection with the accompanied drawing(s). Features that are substantially or functionally equal or similar will be referred to by the same reference sign(s).

FIG. 1 shows a liquid separation system 10, in accordance with embodiments of the present invention, e.g. used in high performance liquid chromatography (HPLC).

FIGS. 2A and 2B show examples of different representations of plural chromatograms, which the data processing unit 70 of FIG. 1 might provide as output based on measurement data sets as received from the detector 50.

FIGS. 3 and 4 shows a schematic selection process of individual measurement data sets of the complete measurement data set 300 by inspecting one after the other measurement data sets and selecting individual ones to create a new subset of measurement data sets.

FIGS. 5A-5C show three selected measurement data sets 302-304 represented as measurement curves. FIG. 5D show five selected measurement data sets represented as measurement curves.

FIGS. 6A-6F illustrate a different embodiment for graphically representing selected measurement data sets.

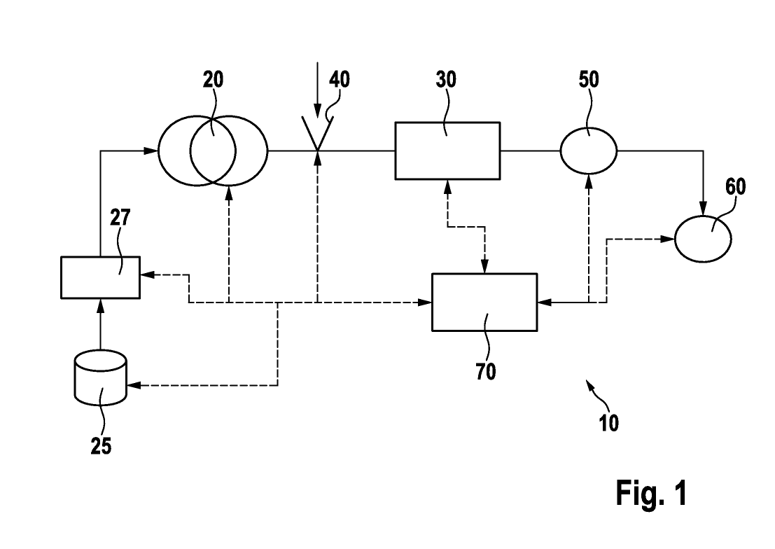

Referring now in greater detail to the drawings, FIG. 1 depicts a general schematic of a liquid separation system 10. A pump 20 receives a mobile phase from a solvent supply 25, typically via a degasser 27, which degasses and thus reduces the amount of dissolved gases in the mobile phase. The pump 20—as a mobile phase drive—drives the mobile phase through a separating device 30 (such as a chromatographic column) comprising a stationary phase. A sampling unit 40 can be provided between the pump 20 and the separating device 30 in order to subject or add (often referred to as sample introduction) a sample fluid into the mobile phase. The stationary phase of the separating device 30 is adapted for separating compounds of the sample liquid. A detector 50 is provided for detecting separated compounds of the sample fluid. A fractionating unit 60 can be provided for outputting separated compounds of sample fluid.

While the mobile phase can be comprised of one solvent only, it may also be mixed from plural solvents. Such mixing might be a low pressure mixing and provided upstream of the pump 20, so that the pump 20 already receives and pumps the mixed solvents as the mobile phase. Alternatively, the pump 20 might be comprised of plural individual pumping units, with plural of the pumping units each receiving and pumping a different solvent or mixture, so that the mixing of the mobile phase (as received by the separating device 30) occurs at high pressure and downstream of the pump 20 (or as part thereof). The composition (mixture) of the mobile phase may be kept constant over time, the so called isocratic mode, or varied over time, the so called gradient mode.

A data processing unit 70, which can be a conventional PC or workstation, might be coupled (as indicated by the dotted arrows) to one or more of the devices in the liquid separation system 10 in order to receive information and/or control operation. For example, the data processing unit 70 might control operation of the pump 20 (e.g. setting control parameters) and receive therefrom information regarding the actual working conditions (such as output pressure, flow rate, etc. at an outlet of the pump). The data processing unit 70 might also control operation of the solvent supply 25 (e.g. setting the solvent/s or solvent mixture to be supplied) and/or the degasser 27 (e.g. setting control parameters such as vacuum level) and might receive therefrom information regarding the actual working conditions (such as solvent composition supplied over time, flow rate, vacuum level, etc.). The data processing unit 70 might further control operation of the sampling unit 40 (e.g. controlling sample injection or synchronization sample injection with operating conditions of the pump 20). The separating device 30 might also be controlled by the data processing unit 70 (e.g. selecting a specific flow path or column, setting operation temperature, etc.), and send—in return—information (e.g. operating conditions) to the data processing unit 70. Accordingly, the detector 50 might be controlled by the data processing unit 70 (e.g. with respect to spectral or wavelength settings, setting time constants, start/stop data acquisition), and send information (e.g. about the detected sample compounds) to the data processing unit 70. The data processing unit 70 might also control operation of the fractionating unit 60 (e.g. in conjunction with data received from the detector 50) and provides data back.

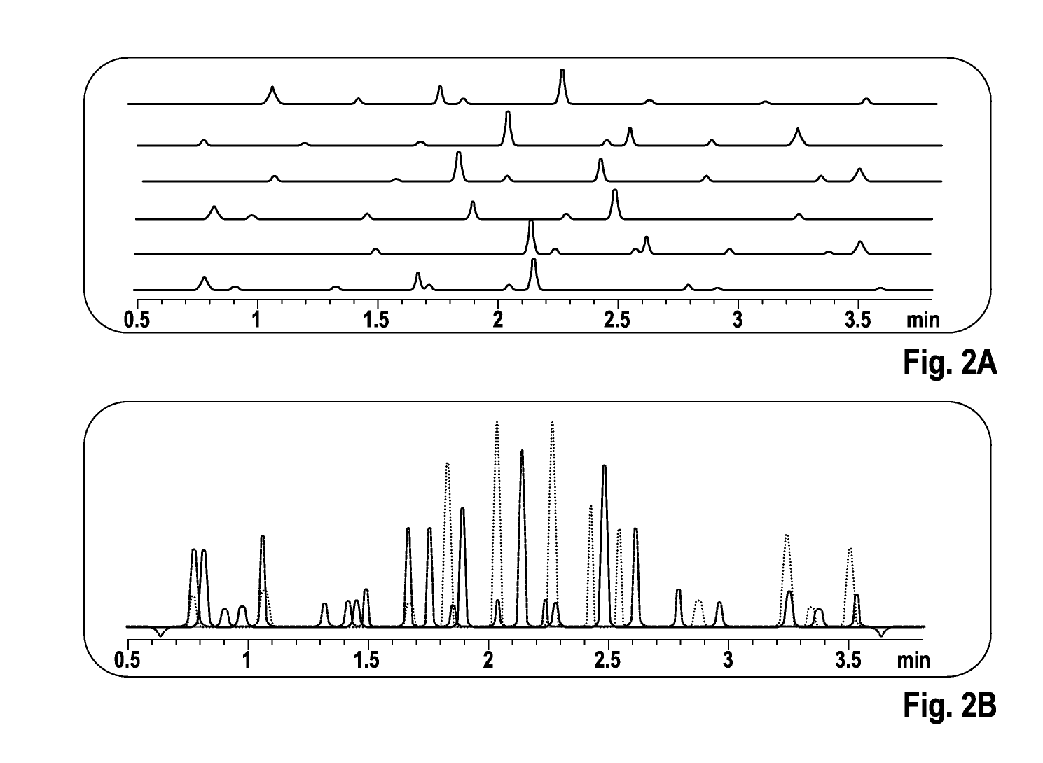

FIGS. 2A and 2B show examples of plural chromatograms, as known in the art, which the data processing unit 70 might provide as output based on measurement data sets as received from the detector 50. Each measurement data set comprises measured results derived during a measurement run or task. In FIG. 2A, each line represents an individual chromatogram showing, for example, absorbance or fluorescence intensity as measured by the detector 50 over time (depicted as abscissa). Each chromatogram in FIG. 2A represents the results of an individual chromatography run, and the chromatograms might have been taken successively one after the other for the same or different samples. Characteristically for representations of measurement data sets as in FIG. 2A is the reduction in size in at least one dimension of each individual measurement data sets. This reduces the ability to distinguish small differences in the dimension that was used for scaling the representation of measurement data sets, for example the intensity in chromatograms.

FIG. 2B shows the same chromatogram plots as in FIG. 2A all displayed in one window in an overlaid mode. Characteristically for representations of measurement data sets as in FIG. 2B is the increase of information in at least one dimension of the measurement data set. This reduces the ability to distinguish differences between the measurement data sets in the dimension that was overlaid.

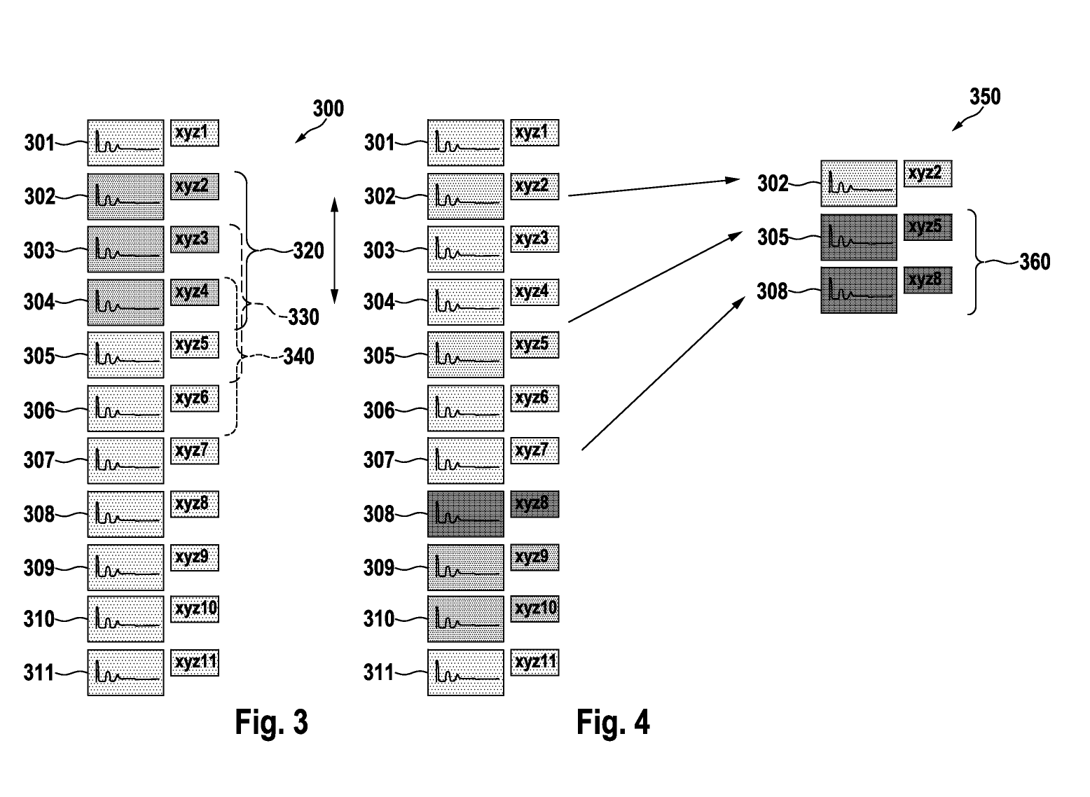

FIGS. 3 and 4 shows a different representation of the measurement data sets 300. FIG. 3 shows eleven measurement data sets 301-311, each being associated with an individual identifier (e.g. identifier “xyz1” for measurement data set 301, identifier “xyz2” for measurement data set 302, etc.).

Displaying all the measurement data sets 300 in one window will look like similar to the representations in FIG. 2A or FIG. 2B. In order to increase comprehensiveness of the data and ease data analysis and comparison, a subset 320 of the measurement data sets 300 can be selected, for example, on a user request. In this example, the user selects the measurement data sets 302-304 as the selected measurement data sets 320, indicated by the bracket for the measurement data sets.

In order to increase the comprehensiveness of the data and ease data analysis and comparison by applying the presented invention, the user can decide to visualize only a maximum of three datasets (e.g. 302-304) and for example with varying transparency of the shown datasets with the primary data set (302) with no transparency, the second one (303) with 50% transparency and the third one (304) with 75% transparency. Upon a change request for example by using the scroll wheel of a computer mouse, the computer will increase or decrease the index of the shown data set by one. Increasing the index, for example, will make dataset 302 invisible, 303 will appear with no transparency (before 50%), 304 will become more visible by decreasing the transparency to 50% (before 75%) and the before invisible dataset 305 will become visible with a transparency of 75%.

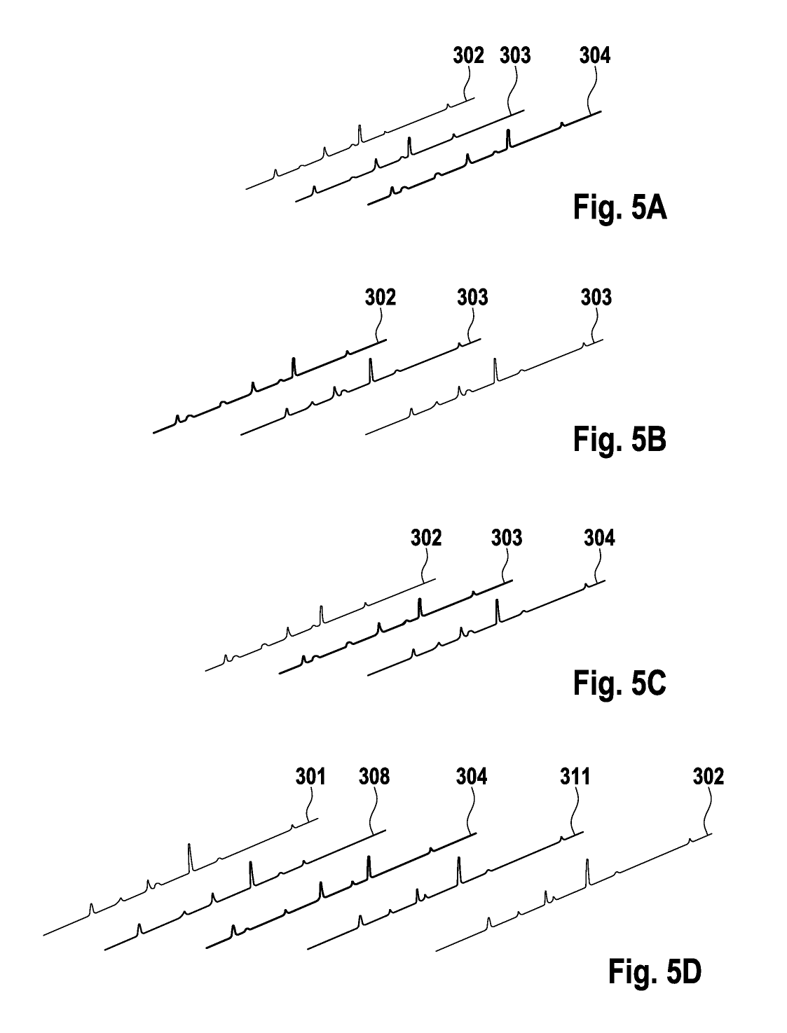

FIG. 4 shows how the user can select certain dataset and review them later in a separate process in the same way. This allows a stepwise approach to review and reduce large datasets to only the important once. The selected measured data sets 320 are then graphically represented in one of the options shown in FIGS. 5A-5C, wherein the three selected measurement data sets 302-304 are represented as measurement curves slightly displaced with respect to each other in a (pseudo) three-dimensional display. For a better visualization of the process, the data set are displayed here in a pseudo-three dimensional display. In a real system these would typically be overlaid

In FIG. 5A, measurement data set 304 is graphically represented as a primary measurement data set in a first graphical style, in this example, as a solid line with zero or almost zero transparency. Measurement data sets 302 and 303 are graphically represented as secondary measurement data sets in a graphical style deviating from the first graphical style with respect to transparency. Measurement data set 303 has a transparency of 50%, and measurement data set 302 has a transparency of 75%.

Upon receipt of a first change request, e.g. scrolling of a mouse coupled to the data processing unit 70 or clicking on an arrow key of a keyboard also coupled to the data processing unit 70, a different one of the selected measurement data sets 320 is represented as the primary measurement data set in the first graphical style, while the two measurement data sets (remaining of the selected measurement data sets 320) are represented as secondary measurement data deviating from the first graphical style. In FIG. 5B, measurement data set 302 is selected as the primary data set and represented with 0% transparency. Measurement data sets 303 and 304 are graphically represented as secondary measurement data sets with measurement data set 303 having 50% transparency, and measurement data set 304 having 75% transparency.

On a further change request, measurement data set 303 is selected as the primary measurement data set and displayed with 0% transparency, while the remaining measurement data sets 302 and 304 are graphically represented as secondary measurement data set with measurement data set 304 having 50% transparency and measurement data set 302 having 75% transparency.

Upon a second change request, which might again be a user request such as a mouse clicking or mouse scrolling but which can also be an automated signal e.g. elapsing after a given period of time, a different plurality of the measurement data sets 300 is selected as to be graphically represented as explained above with respect to FIGS. 5A-5C. Turning back to FIG. 3, this is indicated by reference numeral 330 showing that the measurement data sets with the identifier xyz3, xyz4 and xyz5 are selected. The selected measurement data sets 330 are then graphically represented, for example as explained above with respect to FIGS. 5A-5C.

Upon a next second change request, a different set of measurement data sets 340 can then be selected as indicated in FIG. 3 for the selected measurement data sets 304-306 with identifiers xyz4, xyz5 and xyz6.

In this way, a user can scroll through a large group of measurement data sets in a very intuitive way by selecting only a reduced number of measurement data sets to be displayed, and then clearly distinguishing one of the selected measurement data sets as primary measurement data set, which can then also be varied within the selected measurement data sets by means of the first change request.

It is clear that the number of selected measurement data sets is not limited to any number such as the three measurement data sets as shown in FIG. 5C, but any number of measurement data sets can be selected. In the example of FIG. 5D, five measurement data sets are selected and displayed, e.g. the measurement data sets 301, 308, 304, 311 and 302 are selected. Measurement data set 304 is displayed as primary measurement data set by a solid black line. Measurement data sets 308 and 311 are graphically represented having gray shading being lighter than the solid black line of measurement data set 304, and the measurement data sets 301 and 302 are graphically represented having a gray shade being lighter than the gray shading of measurement data sets 308 and 311. Instead of gray shading, also a variation in transparency (as in FIGS. 5A-5C) could be used, for example, with the primary measurement data sets 304 having 0% transparency, measurement data sets 308 and 311 having 25% transparency, and measurement data set 301 and 302 having 50% transparency. It is also clear that the transparency does not have to be symmetrical with respect to the primary measurement data set, as indicated in the FIG. 5, so that measurement data set 302 might have 20% transparency, measurement data set 311 might have 40% transparency, measurement data set 308 might have 60% transparency, and measurement data set 301 might have 30% transparency. However, it has been found advantageous to provide such symmetry in the graphical representation as it is resembles the effect of optically focusing on a certain “focal plane” with all planes before and behind that focal plane becoming “reduced to background”. This effect may be further increased by using different levels of sharpness of the secondary measurement data sets in the graphical representation.

FIG. 4 shows another example wherein the initial number of measurement data sets 301-311 is reduced, for example by a user interaction, to a subset 350 containing, in this example, only the measurement data sets 302, 305 and 308. The user might then graphically represent the entire subset 350 or again selecting only a number of the measurement data sets, for example, as indicated by the bracket 360 showing only measurement data set 305 and 308 as the selected measurement data sets to be displayed. The aforementioned applies accordingly.

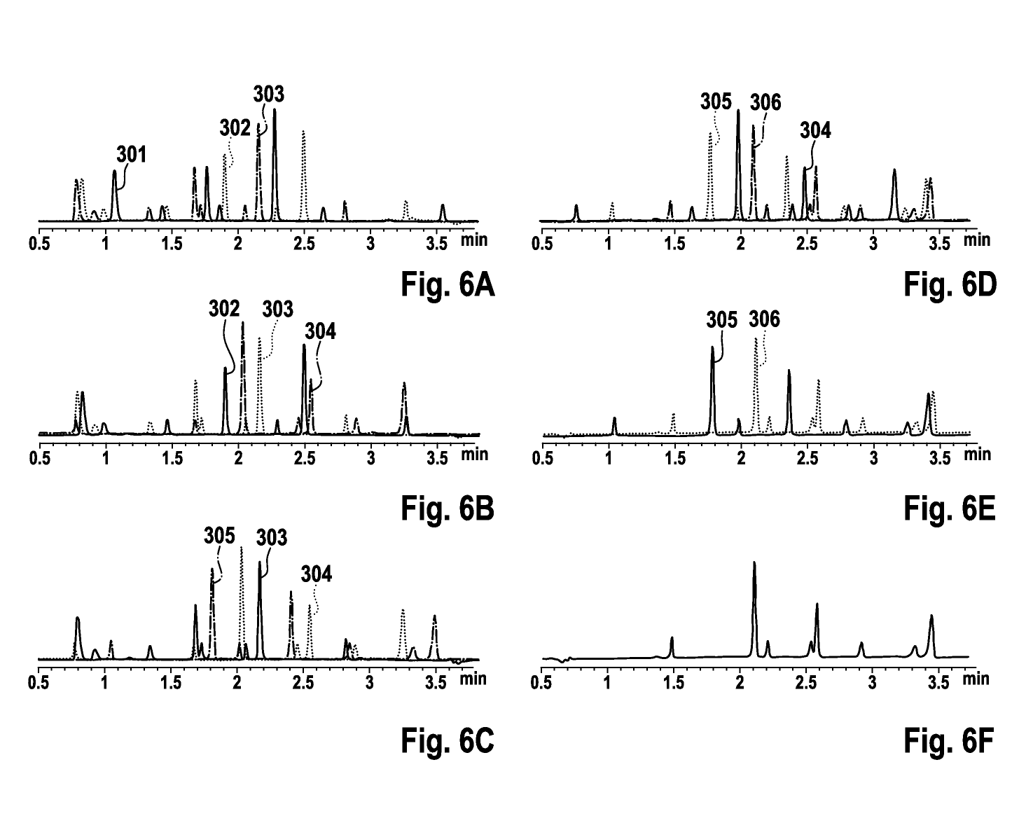

FIGS. 6A-6F show a different embodiment for graphically representing selected measurement data sets. In contrast to the embodiments of FIG. 5, the graphical representation in FIG. 6 is in a two-dimensional representation with one parameter depicted on the abscissa and one the ordinate. In the examples of FIG. 6, the abscissa shows a retention time of a chromatographic separation, and the ordinate either shows absorbance or intensity of fluorescence, dependent on the specific type of detection as used.

FIG. 6A shows selected measurement data sets 320 (relating to FIG. 3A), with the measurement data set 301 being the primary measurement data set depicted in a solid black line, and measurement data sets 301 and 302 being secondary measurement data sets graphically represented using a variation of dotted and/or dashed lines. In the example here, measurement data set 302 is represented as a dotted line, while measurement data set 303 is represented as a combined dotted and dashed line.

The following FIGS. 6B-6F now illustrate view for an embodiment, wherein each Figure graphically represents up to three successive chromatograms according to the measurement data sets 301-306. FIG. 6A shows the measurement data sets 301-303 with the measurement data set 301 being the primary measurement data set, FIG. 6B shows the measurement data sets 302-304 with the measurement data set 302 being the primary measurement data set, FIG. 6C shows the measurement data sets 303-305 with the measurement data set 303 being the primary measurement data set, FIG. 6D shows the measurement data sets 304-306 with the measurement data set 304 being the primary measurement data set, FIG. 6E shows the measurement data sets 305-306 with the measurement data set 305 being the primary measurement data set, and FIG. 6F shows the measurement data set 306 only as the primary measurement data set.

The embodiment of FIGS. 6B-6F thus illustrate a “scan” through the measurement data sets 301-306, with each Fig. showing maximum of three successive measurement data sets and one of those being the primary measurement data set. This “scan” allows to intuitively analyzing through a larger amount of measurement data sets.

Instead of a variation of dotted and/or dashed lines as shown in FIG. 6, a variation in transparency and/or gray shading and/or line sharpness could also be used for distinguishing the primary data set from the secondary measurement data sets. Typically, a variation of the transparency, the shading, or the sharpness of the lines makes the differences between datasets easier to distinguish. The aforementioned applies accordingly, so that upon a second change request a different number of measurement data sets can be selected and graphically represented accordingly. In contrast to representations of a plurality of measurement data sets as in FIGS. 2A and 2B, no loss of information by downsizing one parameter of the measurement data sets or information overflow by overlaying all measurement data sets occurs.

1. A method of graphically representing each of a number of measurement data sets as a variation of at least one parameter, wherein each measurement data set results from a measurement, the method comprising:
[A] selecting a plurality of the measurement data sets to be graphically represented,
[B] graphically representing one of the selected measurement data sets as a primary measurement data set in a first graphical style,
[C] graphically representing each one of the at least one remaining selected measurement data sets as secondary measurement data set in a graphical style deviating in at least one feature from the first graphical style,
and upon a first change request:
graphically representing a different one of the selected measurement data sets as the primary measurement data set in the first graphical style, and continuing with [C].

2. The method of claim 1, wherein in [A], the plurality of the measurement data sets are selected from a group of measurement data sets being larger than the selected plurality of the measurement data sets, so that the selected plurality of the measurement data sets represents a subset of the group of measurement data sets.

3. The method of claim 1, wherein in [A] the plurality of the measurement data sets are selected as:
the primary measurement data set, and
one or more measurement data sets neighboring to the primary measurement data set.

4. The method of claim 3, wherein the measurement data sets are derived successively over time, and the one or more neighboring measurement data sets are selected from the measurement data sets derived in time just before or just after deriving the primary measurement data set.

5. The method of claim 3, wherein each of the measurement data sets is derived for a different value of a second parameter, the second parameter being different from the at least one parameter to be graphically represented for each of the number of measurement data sets, and the one or more neighboring measurement data sets are selected as the measurement data sets with values of the second parameter next or previous to the value of the secondary parameter of the primary measurement data set.

6. The method of claim 1, wherein in [B] and [C], the selected measurement data sets are graphically represented in one window.

7. The method of claim 1, comprising:
upon a second change request:
selecting a different plurality of the measurement data sets to be graphically represented and continuing with [B] and [C].

8. The method of claim 1,
wherein the deviating feature in [C] is at least one of:
transparency,
color shading,
gray shading,
intensity,
line-thickness,
sharpness.

9. The method of claim 1, wherein the first graphical style is a solid line, and the deviating feature in [C] is that the line is non-solid, preferably dotted, dashed, or a combination thereof.

10. The method of claim 1, wherein each measurement data set represents at least one of:
a variation of one parameter over another parameter,
a variation of one parameter over a variation of a different parameter,
a variation of one parameter over time,
a variation of one parameter measured over time,
a chromatogram resulting from a chromatographic separation,
an electrophoretogram resulting from an electrophoretic separation,
an UV-spectrum resulting from UV/VIS spectroscopy,
a MS-spectrum resulting from a mass spectrometry,
a NMR-spectrum resulting from NMR spectroscopy,
an IR-spectrum resulting from one of IR or Raman spectroscopy,
an x-ray-spectrum resulting from x-ray spectroscopy,
a particle-size spectrum resulting from particle-size analysis.

11. The method of claim 1,
wherein graphically representing a respective measurement data set comprises representing the measurement data set in a multi-dimensional, preferably two-dimensional, visualization, with one dimension representing one of the at least one parameter and another dimension representing a parameter causing the variation of the one of the at least one parameter.

12. The method of claim 1,
wherein graphically representing a respective measurement data set comprises representing the measurement data set as a two-dimensional projection of a three-dimensional data set, wherein each measurement data set represents a variation of the third dimension of the three-dimensional data set.

13. The method of claim 1, further comprising
using a scaling of the graphical representation in [B] for providing a scaling of the graphical representation in [C].

14. The method of claim 1, wherein the change request is or comprises one of:
a user request,
a mouse scrolling,
pressing of an arrow key of a computer terminal,
an activation of a computer-human-interaction device,
a time signal,
a time signal after lapsing of a given time interval.

15. The method of claim 1, further comprising analyzing the selected measurement data sets.

16. A software program or product, preferably stored on a data carrier, for controlling or executing the method of claim 1, when run on a data processing system such as a computer.

17. An apparatus for graphically representing each of a number of measurement data sets as a variation of at least one parameter, wherein each measurement data set results from a measurement, the apparatus comprising:
a selector configured for selecting a plurality of the measurement data sets to be graphically represented,
graphical device configured for graphically representing one of the selected measurement data sets as a primary measurement data set in a first graphical style, and for graphically representing each one of the at least one remaining selected measurement data sets as secondary measurement data set in a graphical style deviating in at least one feature from the first graphical style,
a control unit configured for receiving a first change request, and for instructing—upon receipt of the first change request—the graphical device for graphically representing a different one of the selected measurement data sets as the primary measurement data set, and for graphically representing each one of the remaining selected measurement data sets as secondary measurement data set.

18. A fluid separation system for separating compounds of a sample fluid in a mobile phase, the fluid separation system comprising:
a mobile phase drive, preferably a pumping system, adapted to drive the mobile phase through the fluid separation system;
a separation unit, preferably a chromatographic column, adapted for separating compounds of the sample fluid in the mobile phase;
a data processing unit adapted to process data received from the fluid separation system and comprising an apparatus according to claim 16.

19. The fluid separation system of claim 18, further comprising at least one of:
a sample injector adapted to introduce the sample fluid into the mobile phase;
a detector adapted to detect separated compounds of the sample fluid;
a collection unit adapted to collect separated compounds of the sample fluid;
a degassing apparatus for degassing the mobile phase.
